(19) United States
(12) Patent Application Publication
(10) Pub. No.: US 2016/0099198 A1
(43) Pub. Date: Apr. 7, 2016

(54) SEMICONDUCTOR PACKAGE APPARATUS

(71) Applicant: UBIQ Semiconductor Corp., Zhubei City (TW)

(72) Inventor: Chau-Chun Wen, Zhubei City (TW)

(21) Appl. No.: 14/732,130

(22) Filed: Jun. 5, 2015

(30) Foreign Application Priority Data
Oct. 3, 2014 (TW) 103217686
Jan. 15, 2015 (TW) 104101382

(51) Int. Cl. H01L 23/495; H01L 23/00; H01L 23/31; H01L 25/07

(52) U.S. Cl. CPC H01L 23/49575; H01L 23/49562; H01L 25/072; H01L 24/48; H01L 24/40; H01L 23/3107; H01L 24/33; H01L 24/73; H01L 2924/13091; H01L 2224/33181; H01L 2224/32245; H01L 2224/48247; H01L 2224/40245; H01L 2224/73213; H01L 2224/73215; H01L 2224/73263; H01L 2224/73265; H01L 2224/37147; H01L 2224/37012

(57) ABSTRACT

A semiconductor package apparatus includes a lead frame, a first semiconductor chip, a second semiconductor chip, a first connecting element, and a second connecting element. The lead frame includes a power input plate, a ground plate, a phase plate, and a phase detection plate. The second electrode of first semiconductor chip is disposed on the power input plate. The first electrode of second semiconductor chip is disposed on the ground plate. The first connecting element is disposed on the first semiconductor chip and the second semiconductor chip and electrically connects the first electrode of first semiconductor chip with the second electrode of second semiconductor chip. The second connecting element is disposed on the second semiconductor chip and phase plate and electrically connects the second electrode of second semiconductor chip with the phase plate. The first connecting element and the phase detection plate are electrically connected.

### BACKGROUND OF THE INVENTION

1. Field of the Invention

The invention relates to semiconductor package; in particular, to a semiconductor package apparatus capable of effectively enhancing the reliability of electrical connection.

2. Description of the Prior Art

In recent years, with advances in IC technology, electronic products related to the IC technology become more diversified. Among these electronic products, power semiconductor elements (e.g., power transistors) have advantages of high integration density, low static leakage current, and increased power capacity; therefore, the power semiconductor elements have been widely used in many regions such as the switching power supply or the inverter.

In practical applications, the power transistors can be used in a power converter. The power converter can convert an input voltage into different output voltages by switching on or off the power transistors. For example, in order to achieve a voltage step down, a higher input voltage can be converted into a lower output voltage by the power converter.

In conventional circuit structure, there are requirements of electrical connection between the power transistors or between the power transistor and other elements. However, a single L-shape clip is usually used to electrically connect the power transistors in conventional power module package structures. Since the L-shape clip has to electrically connect the power transistors, the L-shape clip is too long and its distal end will be warped, the reliability of electrical connection will also become poor. In addition, since the L-shape clip needs to connect too many points, it will be uneven and cause some problems such as open circuit or poor electrical connection.

### SUMMARY OF THE INVENTION

Therefore, the invention provides a semiconductor package apparatus capable of effectively enhancing the reliability of electrical connection to solve the above-mentioned problems occurred in the prior arts.

An embodiment of the invention is a semiconductor package apparatus. In this embodiment, the semiconductor package apparatus includes a lead frame, a first semiconductor chip, a second semiconductor chip, a first connecting element, and a second connecting element. The lead frame includes a power input plate, a ground plate, a phase plate, and a phase detection plate. The first semiconductor chip has a first electrode and a second electrode. The second electrode of the first semiconductor chip is disposed on the power input plate. The second semiconductor chip has a first electrode and a second electrode. The first electrode of the second semiconductor chip is disposed on the ground plate. The first connecting element is disposed on the first semiconductor chip and the second semiconductor chip and the first connecting element is electrically connected with the first electrode of the first semiconductor chip and the second electrode of the second semiconductor chip. The second connecting element is disposed on the second semiconductor chip and the phase plate and the second connecting element is electrically connected with the second electrode of the second semiconductor chip and the phase plate. Wherein, the first connecting element and the phase detection plate are electrically connected.

In an embodiment, the semiconductor package apparatus further includes a third connecting element. The third connecting element is disposed on the first semiconductor chip and the phase detection plate. The third connecting element is electrically connected with the first electrode of the first semiconductor chip and the phase detection plate.

In an embodiment, the third connecting element is a bonding wire or a clip.

In an embodiment, the first connecting element is a clip.

In an embodiment, the second connecting element is a clip or a ribbon cable.

In an embodiment, the second electrode of the first semiconductor chip faces the power input plate.

In an embodiment, the first electrode of the second semiconductor chip faces the ground plate.

In an embodiment, the first connecting element and the second connecting element are separated from each other.

In an embodiment, the first connecting element and the second connecting element are at least partially overlapped.

In an embodiment, a top-view shape of the first connecting element and a top-view shape of the second connecting element are complementary.

In an embodiment, the second semiconductor chip is a lateral double-diffused metal-oxide-semiconductor field-effect transistor (LDMOS).

In an embodiment, the first semiconductor chip and the second semiconductor chip are vertical-type metal-oxide-semiconductor field-effect transistors (MOSFETs), and the second semiconductor chip is a flip chip.

In an embodiment, the first electrode and the second electrode of the first semiconductor chip and the second semiconductor chip are source electrodes and drain electrodes respectively.

In an embodiment, the semiconductor package apparatus includes a molding compound used for encapsulating the first semiconductor chip and the second semiconductor chip.

In an embodiment, at least a part of the first semiconductor chip and the second semiconductor chip exposed to the molding compound.

In an embodiment, the first connecting element and the second connecting element are copper sheets.

In an embodiment, a side-view shape of the second connecting element is Z-shape.

In an embodiment, a side-view shape of the third connecting element is Z-shape.

In an embodiment, a connecting part of the first connecting element electrically connected with the first semiconductor chip and the second semiconductor chip has an uneven shape.

In an embodiment, a connecting part of the second connecting element electrically connected with the second semiconductor chip has an uneven shape.

In an embodiment, a connecting part of the first connecting element electrically connected with the first semiconductor chip and the second semiconductor chip has a recess approximately corresponding to a conductive adhesive layer disposed on the first semiconductor chip and the second semiconductor chip.

In an embodiment, a connecting part of the second connecting element electrically connected with the second semiconductor chip has a recess approximately corresponding to a conductive adhesive layer disposed on the second semiconductor chip.

Compared to the prior arts, the semiconductor package apparatus of the invention uses at least two connecting elements separated from each other to electrically connect the power transistors instead of the conventional single L-shaped clip. Since each connecting element in the invention only needs to connect fewer power transistors than the conventional L-shaped clip, it can be shorter than the conventional L-shaped clip and its distal end will be not warped to increase the reliability of electrical connection. In addition, each connecting element in the invention has fewer points to connect, it will be even and the problems such as open circuit or poor electrical connection in the prior art can be improved. Moreover, since the total area of the connecting elements in the invention is similar to the area of the conventional L-shaped clip, the heat dissipating effect of the entire semiconductor package apparatus will not be affected and the process costs will not be increased.

The advantage and spirit of the invention may be understood by the following detailed descriptions together with the appended drawings.

### BRIEF DESCRIPTION OF THE APPENDED DRAWINGS

FIG. 1 illustrates a circuit schematic diagram of the power converter in an embodiment of the invention.

FIG. 2 illustrates a cross-section of the semiconductor package apparatus in an embodiment of the invention.

FIG. 3 illustrates a top view of the semiconductor package apparatus of FIG. 2.

FIG. 4 and FIG. 5 illustrate top views of the semiconductor package apparatus in different embodiments of the invention respectively.

FIG. 6, FIG. 7, FIG. 8, and FIG. 9 illustrate cross-sections of the semiconductor package apparatus in different embodiments of the invention.

### DETAILED DESCRIPTION OF THE INVENTION

Exemplary embodiments of the present invention are referenced in detail now, and examples of the exemplary embodiments are illustrated in the drawings. Further, the same or similar reference numerals of the elements/components in the drawings and the detailed description of the invention are used on behalf of the same or similar parts. In the following embodiments, if an element is “connected” or “coupled” to another element, the element may be directly connected or coupled to the another element, or there may be any elements or specific materials (e.g., colloid or solder) disposed between the element and the another element.

A preferred embodiment of the invention is a semiconductor package apparatus. In this embodiment, the semiconductor package apparatus can be used to package a power module, a half-bridge module, or an output stage of a power converter, but not limited to this.

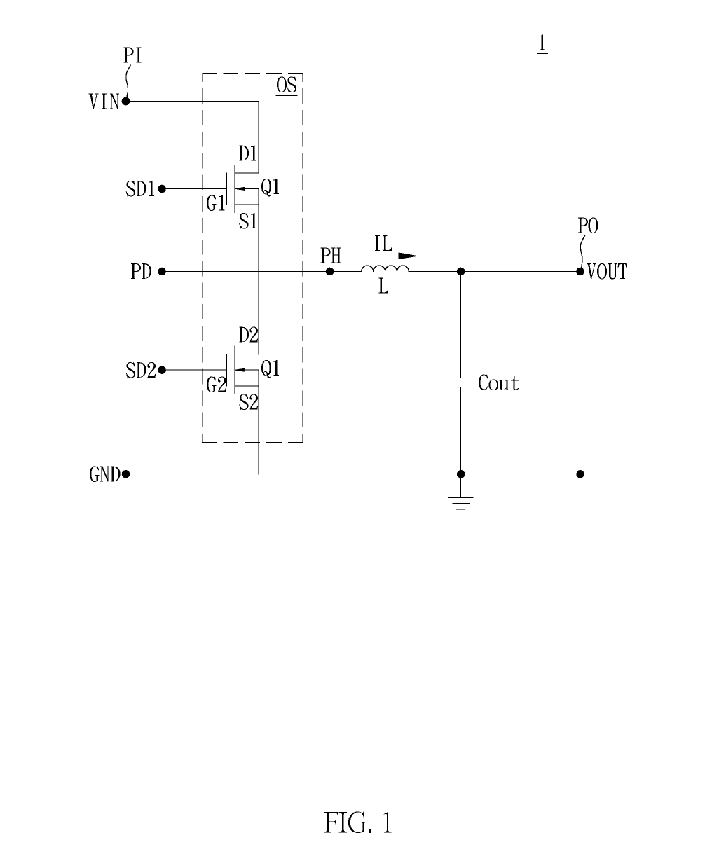

Please refer to FIG. 1. FIG. 1 illustrates a circuit schematic diagram of the power converter in this embodiment. As shown in FIG. 1, the power converter 1 can be a DC-DC converter, but not limited to this. The output stage OS of the power converter 1 includes a high-side N-type transistor Q1 and a low-side N-type transistor Q2 and an input voltage V_{IN} is converted into a lower output voltage V_{OUT} through the high-side N-type transistor Q1 and the low-side N-type transistor Q2.

It should be noticed that although the high-side N-type transistor Q1 and the low-side N-type transistor Q2 used in this embodiment are both power transistors, transistors or semiconductor chips of other types can be also used in other embodiments, not limited to this.

In an embodiment, a driving chip (not shown in FIG. 1) can use driving control signals SD1 and SD2 to switch on or off a gate electrode G1 of the high-side N-type transistor Q1 and a gate electrode G2 of the low-side N-type transistor Q2 respectively to convert the input voltage V_{IN} into the lower output voltage V_{OUT}. In another embodiment, the high-side N-type transistor Q1, the low-side N-type transistor Q2, and the driving chip can be integrated into a single package object which is called “a DrMOS package object” in the industry. In practical applications, the driving chip and a pulse-width modulation (PWM) control chip can be integrated into a controller, but not limited to this.

In an embodiment, a drain electrode D1 of the high-side N-type transistor Q1 is electrically connected with a power input plate PI of a lead frame to receive the input voltage V_{IN}. A source electrode S2 of the low-side N-type transistor Q2 is electrically connected with a ground plate GND of the lead frame. A source electrode S1 of the high-side N-type transistor Q1 and a drain electrode D2 of the low-side N-type transistor Q2 are electrically connected with a phase plate PH of the lead frame. An output inductor L is electrically connected between the phase plate PH and an output terminal PO. An output current I_{L} outputted by the output stage OS of the power converter 1 flows through the output inductor L and the lower output voltage V_{OUT} is formed at the output terminal PO. In another embodiment, the phase plate PH can be also called “an output plate”, but not limited to this.

In an embodiment, the source electrode S1 of the high-side N-type transistor Q1 and the drain electrode D2 of the low-side N-type transistor Q2 are not only electrically connected with the phase plate PH of the lead frame, but also electrically connected with a phase detection plate PD of the lead frame. Therefore, a lot of related information can be obtained from the phase detection plate PD of the lead frame. For example, the related information such as input voltage information, a protection circuit parameter, or a load current sensing can be obtained from the phase detection plate PD.

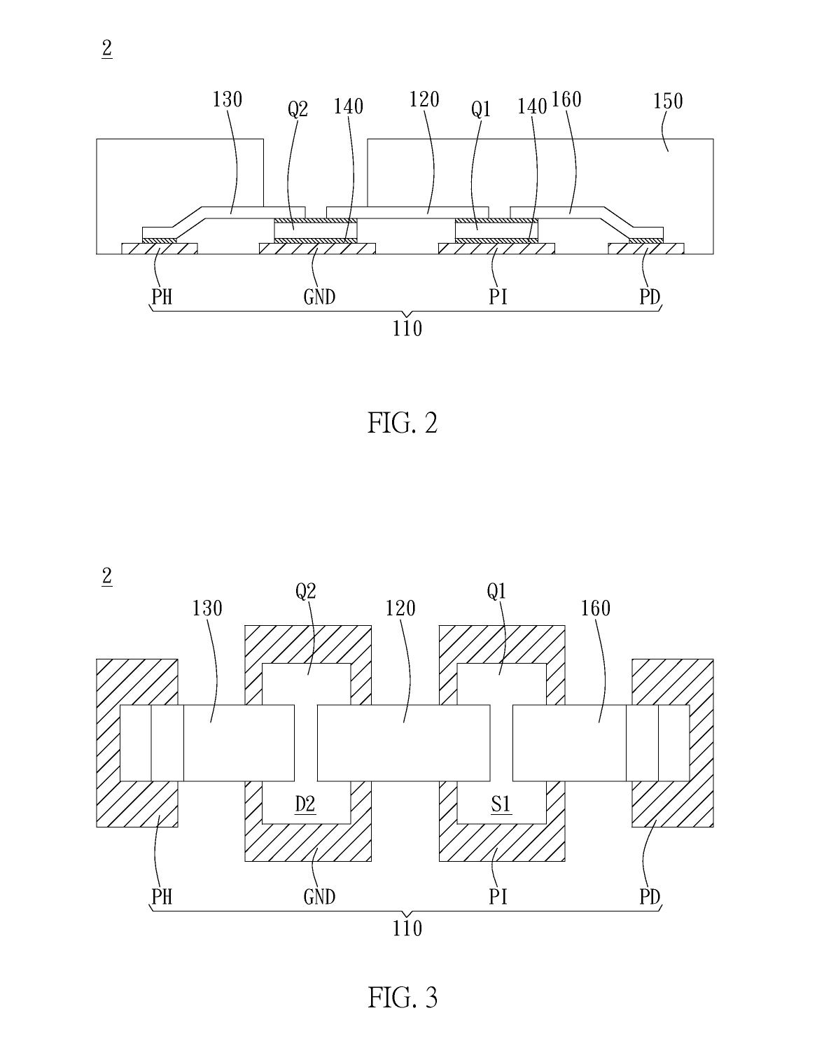

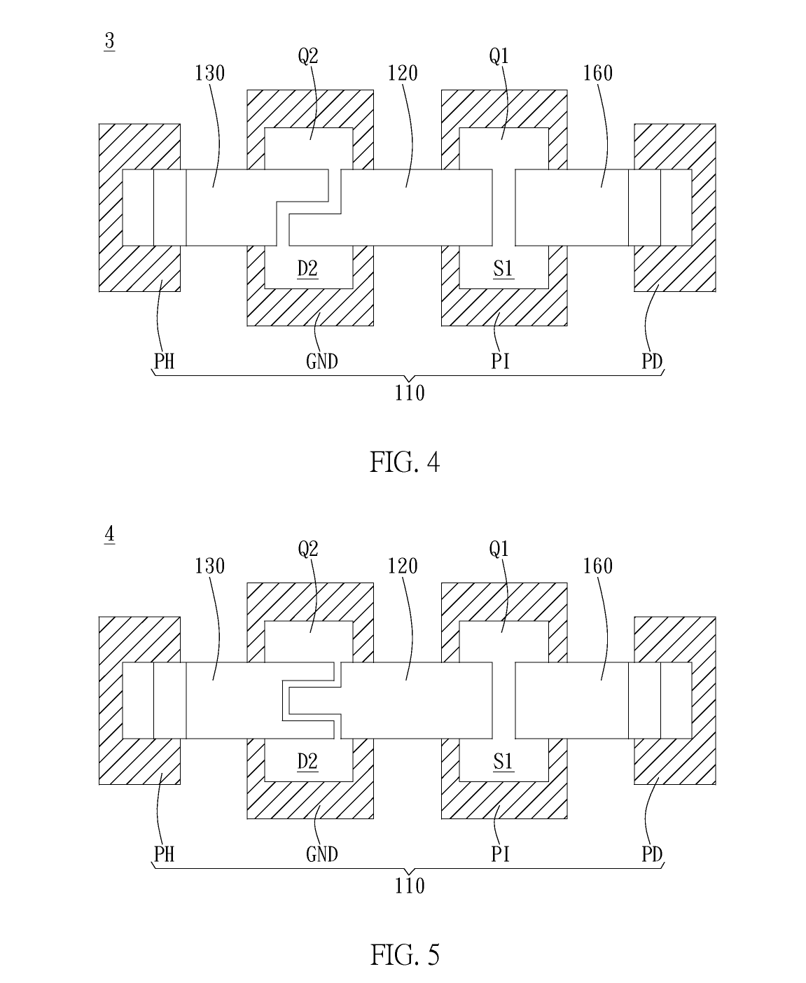

Please refer to FIG. 2 and FIG. 3. FIG. 2 illustrates a cross-section of the semiconductor package apparatus in an embodiment of the invention. FIG. 3 illustrates a top view of the semiconductor package apparatus of FIG. 2. As shown in FIG. 2 and FIG. 3, the semiconductor package apparatus 2 includes a lead frame 110, a high-side N-type transistor Q1, a low-side N-type transistor Q2, a first connecting element 120, a second connecting element 130, and a third connecting element 160. The lead frame 110 includes a power input plate PI, a ground plate GND, a phase plate PH, and a phase detection plate PD.

Next, the elements of the semiconductor package apparatus 2 are introduced in detail respectively.

The high-side N-type transistor Q1 is disposed on the power input plate PI. A drain electrode D1 of the high-side N-type transistor Q1 faces the power input plate PI and it can be electrically connected with the power input plate PI through a conductive adhesive layer 140 to obtain the input voltage V_{IN} from the power input plate PI. By doing so, the heat generated when the high-side N-type transistor Q1 is operated can be dissipated through the power input plate PI. In an embodiment, the conductive adhesive layer 140 can be a solder, but not limited to this.

In practical applications, the drain electrode D1 of the high-side N-type transistor Q1 can be also electrically connected with the power input plate PI through a hot-pressing method or other methods without specific limitations. In an embodiment, the high-side N-type transistor Q1 can be a vertical-type transistor, such as a trench-type transistor, but not limited to this.

The low-side N-type transistor Q2 is disposed on the ground plate GND. A source electrode S2 of the low-side N-type transistor Q2 faces the ground plate GND and it can be electrically connected with the ground plate GND through the conductive adhesive layer 140. By doing so, the heat generated when the low-side N-type transistor Q2 is operated can be dissipated through the ground plate GND.

In practical applications, the source electrode S2 of the low-side N-type transistor Q2 can be also electrically connected with the ground plate GND through a hot-pressing method or other methods without specific limitations. In an embodiment, the low-side N-type transistor Q2 can be a horizontal-type transistor, such as a lateral double-diffused metal-oxide-semiconductor field-effect transistor (LDMOS), but not limited to this. In another embodiment, the low-side N-type transistor Q2 can be also a vertical-type transistor, and the low-side N-type transistor Q2 is a flip chip, but not limited to this.

The first connecting element 120 is disposed on the high-side N-type transistor Q1 and the low-side N-type transistor Q2, so that the high-side N-type transistor Q1 and the low-side N-type transistor Q2 can be electrically connected through the first connecting element 120.

In an embodiment, the first connecting element 120 can be not only electrically connected with the source electrode S1 of the high-side N-type transistor Q1 through the conductive adhesive layer 140, but also electrically connected with the drain electrode D2 of the low-side N-type transistor Q2 through the conductive adhesive layer 140. Therefore, the source electrode S1 of the high-side N-type transistor Q1 and the drain electrode D2 of the low-side N-type transistor Q2 can be electrically connected through the first connecting element 120.

In practical applications, the first connecting element 120 can be also electrically connected with the source electrode S1 of the high-side N-type transistor Q1 and the drain electrode D2 of the low-side N-type transistor Q2 through a hot-pressing method or other methods without specific limitations. In an embodiment, the first connecting element 120 can be a clip, such as a copper sheet or a copper film, but not limited to this.

The second connecting element 130 is disposed on the low-side N-type transistor Q2 and the phase plate PH, so that the low-side N-type transistor Q2 and the phase plate PH can be electrically connected through the second connecting element 130. In an embodiment, the second connecting element 130 can be not only electrically connected with the drain electrode D2 of the low-side N-type transistor Q2 through the conductive adhesive layer 140, but also electrically connected with the phase plate PH through the conductive adhesive layer 140. Therefore, the drain electrode D2 of the low-side N-type transistor Q2 and the phase plate PH can be electrically connected through the second connecting element 130.

In practical applications, the second connecting element 130 can be also electrically connected with the drain electrode D2 of the low-side N-type transistor Q2 and the phase plate PH through a hot-pressing method or other methods without specific limitations. In an embodiment, the second connecting element 130 can be a clip, such as a copper sheet or a copper film; in another embodiment, the second connecting element 130 can be a ribbon cable, but not limited to this.

It should be noticed that although the first connecting element 120 and the second connecting element 130 are both disposed on the low-side N-type transistor Q2 and both electrically connected with the drain electrode D2 of the low-side N-type transistor Q2, the first connecting element 120 and the second connecting element 130 are separated from each other. In an embodiment, the thickness of the first connecting element 120 and the second connecting element 130 can be 25 μm˜75 μm, but not limited to this.

In an embodiment, a side-view shape of the second connecting element 130 can be a Z-shape to facilitate the bonding or electrical connection between the second connecting element 130 and the phase plate PH, but not limited to this. That is to say, with this feature, the second connecting element 130 has enough area to be bonded or electrically connected with the phase plate PH, so that the reliability of the electrical connection between the second connecting element 130 and the phase plate PH can be effectively improved.

It should be noticed that the single clip in the prior art has to electrically connect at least three points (e.g., a high-side N-type transistor, a low-side N-type transistor, and a phase plate); however, both the first connecting element 120 and the second connecting element 130 in this embodiment only electrically connect two points to achieve the electrical connection between the elements, so that the problems of warping, poor connection, or shedding occurred in the prior art can be avoided and the semiconductor package apparatus 2 of the invention can have better electrical connection reliability. In addition, the first connecting element 120 and the second connecting element 130 in this embodiment occupy smaller space than the conventional wire bonding method does, and the distance between the high-side N-type transistor Q1 and the low-side N-type transistor Q2 can be also decreased.

The third connecting element 160 is disposed on the high-side N-type transistor Q1 and the phase detection plate PD, so that the high-side N-type transistor Q1 and the phase detection plate PD can be electrically connected through the third connecting element 160.

In an embodiment, the third connecting element 160 can be not only electrically connected with the source electrode S1 of the high-side N-type transistor Q1 through the conductive adhesive layer 140, but also electrically connected with the phase detection plate PD through the conductive adhesive layer 140, so that the source electrode S1 of the high-side N-type transistor Q1 and the phase detection plate PD can be electrically connected through the first connecting element 120.

In practical applications, the third connecting element 160 can be also electrically connected with the source electrode S1 of the high-side N-type transistor Q1 and the phase detection plate PD through a hot-pressing method or other methods without specific limitations. In an embodiment, the third connecting element 160 can be a clip; in another embodiment, the third connecting element 160 can be a bonding wire; in another embodiment, the third connecting element 160 can be a ribbon cable, but not limited to this.

In an embodiment, a side-view shape of the third connecting element 160 can be a Z-shape to facilitate the bonding or electrical connection between the third connecting element 160 and the phase detection plate PD, but not limited to this. That is to say, the third connecting element 160 should have enough area to be bonded or electrically connected with the phase detection plate PD, so that the reliability of the electrical connection between the third connecting element 160 and the phase detection plate PD can be effectively improved.

In an embodiment, the semiconductor package apparatus 2 of the invention can further include a molding compound 150 to encapsulate the high-side N-type transistor Q1 and the low-side N-type transistor Q2 to prevent the high-side N-type transistor Q1 and the low-side N-type transistor Q2 from being corroded or damaged by water vapor or other substances. In addition, the molding compound 150 can expose at least a part of the first connecting element 120 and the second connecting element 130. In another embodiment, the molding compound 150 can also expose a part of the first connecting element 120, a part of the second connecting element 130, a part of the third connecting element 160, or their combinations to dissipate the heat generated when the high-side N-type transistor Q1 and the low-side N-type transistor Q2 are operated, but not limited to this.

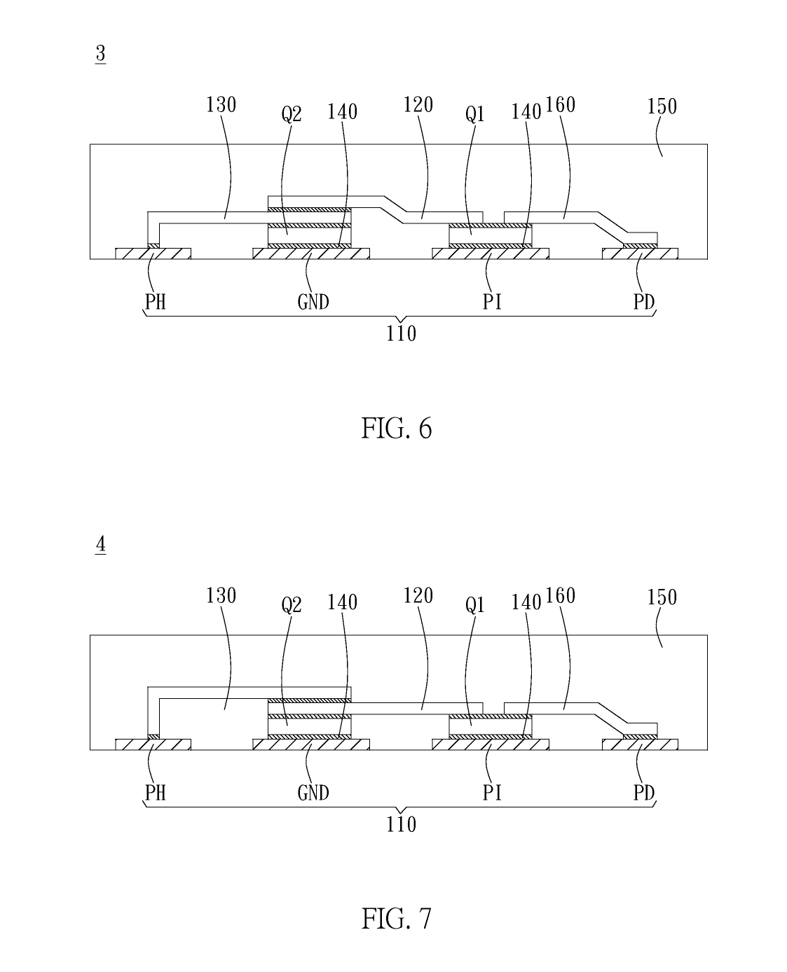

Please refer to FIG. 4. FIG. 4 illustrates a top view of the semiconductor package apparatus in another embodiment of the invention. The main feature of the semiconductor package apparatus 3 of FIG. 4 is that a top-view shape of the first connecting element 120 and a top-view shape of the second connecting element 130 are complementary. By doing so, the first connecting element 120 and the second connecting element 130 have corresponding top-view shapes. Therefore, when the position aligning process is performed, it is easier to precisely dispose the first connecting element 120 on the high-side N-type transistor Q1 and the low-side N-type transistor Q2 and precisely dispose the second connecting element 130 on the low-side N-type transistor Q2 and the phase plate PH.

Please refer to FIG. 5. FIG. 5 illustrates a top view of the semiconductor package apparatus in another embodiment of the invention. In the semiconductor package apparatus 4 of FIG. 5, a top-view shape of the first connecting element 120 and a top-view shape of the second connecting element 130 are also complementary. Therefore, when the position aligning process is performed, it is easier to precisely dispose the first connecting element 120 on the high-side N-type transistor Q1 and the low-side N-type transistor Q2 and precisely dispose the second connecting element 130 on the low-side N-type transistor Q2 and the phase plate PH.

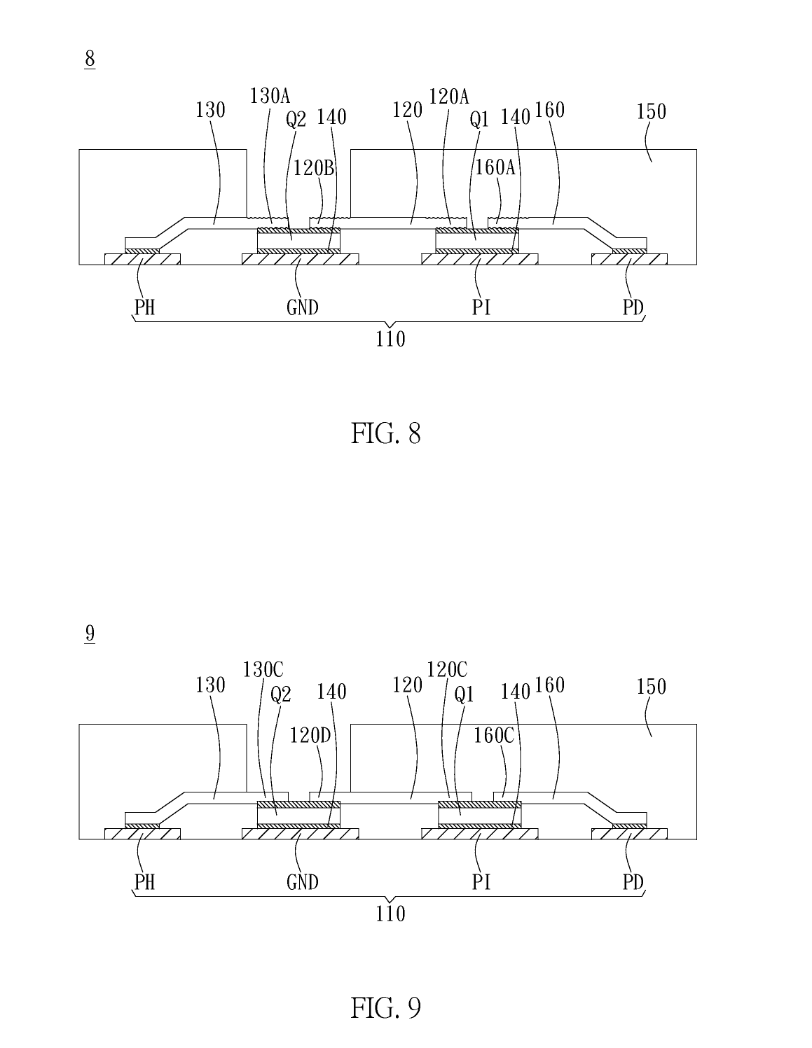

Please refer to FIG. 6. FIG. 6 illustrates a cross-section of the semiconductor package apparatus in another embodiment of the invention. After comparing FIG. 6 with FIG. 2, it can be found that the difference between FIG. 6 and FIG. 2 is that the first connecting element 120 and the second connecting element 130 of FIG. 6 are at least partially overlapped, and the first connecting element 120 is disposed above the second connecting element 130. Therefore, in this embodiment, the source electrode S1 of the high-side N-type transistor Q1 and the drain electrode D2 of the low-side N-type transistor Q2 are electrically connected through the overlapped first connecting element 120 and second connecting element 130, but not limited to this.

Please refer to FIG. 7. FIG. 7 illustrates a cross-section of the semiconductor package apparatus in another embodiment of the invention. After comparing FIG. 7 with FIG. 2, it can be found that the difference between FIG. 7 and FIG. 2 is that the first connecting element 120 and the second connecting element 130 of FIG. 7 are at least partially overlapped, and the first connecting element 120 is disposed under the second connecting element 130. Therefore, in this embodiment, the drain electrode D2 of the low-side N-type transistor Q2 and the phase plate PH are electrically connected through the overlapped first connecting element 120 and second connecting element 130, but not limited to this.

It should be noticed that when the above-mentioned first connecting element, second connecting element, and/or third connecting element are clips, in order to make the first connecting element, second connecting element, and/or third connecting element more tightly connected with the high-side N-type transistor and the low-side N-type transistor, the invention further provides two different types of connecting element as follows.

(1) If the first connecting element, the second connecting element, and the third connecting element are all clips, as shown in FIG. 8, a connecting part 120A of the first clip 120 electrically connecting with the high-side N-type transistor Q1 has an uneven shape, so that the connecting part 120A of the first clip 120 can be more tightly connected with the conductive adhesive layer 140 (e.g., the solder) on the high-side N-type transistor Q1.

Similarly, a connecting part 120B of the first clip 120 electrically connecting with the low-side N-type transistor Q2 also has an uneven shape, so that the connecting part 120B of the first clip 120 can be more tightly connected with the conductive adhesive layer 140 (e.g., the solder) on the low-side N-type transistor Q2; a connecting part 130A of the second clip 130 electrically connecting with the low-side N-type transistor Q2 also has an uneven shape, so that the connecting part 130A of the second clip 130 can be more tightly connected with the conductive adhesive layer 140 (e.g., the solder) on the low-side N-type transistor Q2; a connecting part 160A of the third clip 160 electrically connecting with the high-side N-type transistor Q1 has an uneven shape, so that the connecting part 160A of the third clip 160 can be more tightly connected with the conductive adhesive layer 140 (e.g., the solder) on the high-side N-type transistor Q1.

(2) If the first connecting element, the second connecting element, and the third connecting element are all clips, as shown in FIG. 8, a connecting part of the first clip 120 electrically connecting with the high-side N-type transistor Q1 has a recess 120C approximately corresponding to a conductive adhesive layer 140 disposed on the high-side N-type transistor Q1, so that the conductive adhesive layer 140 can be contained in the recess 120C of the first clip 120, and the first clip 120 can be more tightly connected with the high-side N-type transistor Q1.

Similarly, a connecting part of the first clip 120 electrically connecting with the low-side N-type transistor Q2 has a recess 120D approximately corresponding to a conductive adhesive layer 140 disposed on the low-side N-type transistor Q2, so that the conductive adhesive layer 140 can be contained in the recess 120D of the first clip 120, and the first clip 120 can be more tightly connected with the low-side N-type transistor Q2; a connecting part of the second clip 130 electrically connecting with the low-side N-type transistor Q2 has a recess 130C approximately corresponding to a conductive adhesive layer 140 disposed on the low-side N-type transistor Q2, so that the conductive adhesive layer 140 can be contained in the recess 130C of the second clip 130, and the second clip 130 can be more tightly connected with the low-side N-type transistor Q2; a connecting part of the third clip 160 electrically connecting with the high-side N-type transistor Q1 has a recess 160C approximately corresponding to a conductive adhesive layer 140 disposed on the high-side N-type transistor Q1, so that the conductive adhesive layer 140 can be contained in the recess 160C of the third clip 160, and the third clip 160 can be more tightly connected with the high-side N-type transistor Q1.

In practical applications, it is not necessary that the first connecting element 120, the second connecting element 130, and the third connecting element 160 are all clips, and the connecting element is not limited to the uneven shape or the recess mentioned above. Any types of connecting element capable of being more tightly connected with the chips can be used as the connecting elements in the embodiment.

Compared to the prior arts, the semiconductor package apparatus of the invention uses at least two connecting elements separated from each other to electrically connect the power transistors instead of the conventional single L-shaped clip. Since each connecting element in the invention only needs to connect fewer power transistors than the conventional L-shaped clip, it can be shorter than the conventional L-shaped clip and its distal end will be not warped to increase the reliability of electrical connection. In addition, each connecting element in the invention has fewer points to connect, it will be even and the problems such as open circuit or poor electrical connection in the prior art can be improved. Moreover, since the total area of the connecting elements in the invention is similar to the area of the conventional L-shaped clip, the heat dissipating effect of the entire semiconductor package apparatus will not be affected and the process costs will not be increased.

With the example and explanations above, the features and spirits of the invention will be hopefully well described. Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A semiconductor package apparatus, comprising:
a lead frame, including a power input plate, a ground plate, a phase plate, and a phase detection plate;
a first semiconductor chip, having a first electrode and a second electrode, wherein the second electrode of the first semiconductor chip is disposed on the power input plate;
a second semiconductor chip having a first electrode and a second electrode, wherein the first electrode of the second semiconductor chip is disposed on the ground plate;
a first connecting element, disposed on the first semiconductor chip and the second semiconductor chip, wherein the first connecting element is electrically connected with the first electrode of the first semiconductor chip and the second electrode of the second semiconductor chip; and
a second connecting element, disposed on the second semiconductor chip and the phase plate, wherein the second connecting element is electrically connected with the second electrode of the second semiconductor chip and the phase plate,
wherein the first connecting element and the phase detection plate are electrically connected.

2. The semiconductor package apparatus of claim 1, further comprising:
a third connecting element, disposed on the first semiconductor chip and the phase detection plate, wherein the third connecting element is electrically connected with the first electrode of the first semiconductor chip and the phase detection plate.

3. The semiconductor package apparatus of claim 2, wherein the third connecting element is a bonding wire or a clip.

4. The semiconductor package apparatus of claim 1, wherein the first connecting element is a clip.

5. The semiconductor package apparatus of claim 1, wherein the second connecting element is a clip or a ribbon cable.

6. The semiconductor package apparatus of claim 1, wherein the second electrode of the first semiconductor chip faces the power input plate.

7. The semiconductor package apparatus of claim 1, wherein the first electrode of the second semiconductor chip faces the ground plate.

8. The semiconductor package apparatus of claim 1, wherein the first connecting element and the second connecting element are separated from each other.

9. The semiconductor package apparatus of claim 1, wherein the first connecting element and the second connecting element are at least partially overlapped.

10. The semiconductor package apparatus of claim 1, wherein a top-view shape of the first connecting element and a top-view shape of the second connecting element are complementary.

11. The semiconductor package apparatus of claim 1, wherein the second semiconductor chip is a lateral double-diffused metal-oxide-semiconductor field-effect transistor (LDMOS).

12. The semiconductor package apparatus of claim 1, wherein the first semiconductor chip and the second semiconductor chip are vertical-type metal-oxide-semiconductor field-effect transistors (MOSFETs), and the second semiconductor chip is a flip chip.

13. The semiconductor package apparatus of claim 1, wherein the first electrode and the second electrode of the first semiconductor chip and the second semiconductor chip are source electrodes and drain electrodes respectively.

14. The semiconductor package apparatus of claim 1, further comprising:
a molding compound, for encapsulating the first semiconductor chip and the second semiconductor chip.

15. The semiconductor package apparatus of claim 14, wherein at least a part of the first semiconductor chip and the second semiconductor chip exposed to the molding compound.

16. The semiconductor package apparatus of claim 1, wherein the first connecting element and the second connecting element are copper sheets.

17. The semiconductor package apparatus of claim 1, wherein a side-view shape of the second connecting element is Z-shape.

18. The semiconductor package apparatus of claim 1, wherein a side-view shape of the third connecting element is Z-shape.

19. The semiconductor package apparatus of claim 1, wherein a connecting part of the first connecting element electrically connected with the first semiconductor chip and the second semiconductor chip has an uneven shape.

20. The semiconductor package apparatus of claim 1, wherein a connecting part of the second connecting element electrically connected with the second semiconductor chip has an uneven shape.

21. The semiconductor package apparatus of claim 1, wherein a connecting part of the first connecting element electrically connected with the first semiconductor chip and the second semiconductor chip has a recess approximately corresponding to a conductive adhesive layer disposed on the first semiconductor chip and the second semiconductor chip.

22. The semiconductor package apparatus of claim 1, wherein a connecting part of the second connecting element electrically connected with the second semiconductor chip has a recess approximately corresponding to a conductive adhesive layer disposed on the second semiconductor chip.
